(19) United States
(12) Patent Application Publication
(10) Pub. No.: US 2010/0012576 A1
(43) Pub. Date: Jan. 21, 2010

(54) NANOPOROUS CARBONACEOUS MEMBRANES AND RELATED METHODS

(75) Inventors: Elizabeth Nola Hoffman, Aiken, SC (US); Gleb Yushin, Atlanta, GA (US); Yury Gogotsi, Warminster, PA (US); Michel W. Barsoum, Moorestown, NJ (US)

Correspondence Address: WOODCOCK WASHBURN LLP, CIRA CENTRE, 12TH FLOOR, 2929 ARCH STREET, PHILADELPHIA, PA, 19104-2891, US

(73) Assignee: Drexel University

(21) Appl. No.: 12/300,399

(22) PCT Filed: May 11, 2007
(86) PCT No.: PCT/US07/11442

§ 371 Date: Mar. 26, 2009

Related U.S. Application Data
(60) Provisional application No. 60/799,980, filed on May 12, 2006.

(51) Int. Cl. B01D 71/02; C23C 16/32; C23C 16/34; C23C 14/34; B32B 3/26; B01D 67/00

(52) U.S. Cl. 210/496; 428/221; 427/249.1; 204/192.15; 427/245; 428/315.5; 96/11

(57) ABSTRACT

Disclosed are nanoporous carbonaceous membranes and related devices, along with associated methods.

### CROSS-REFERENCE TO RELATED APPLICATIONS

This application claims the benefit of U.S. Provisional Application No. 60/799,980, filed on May 12, 2006, the entirety of which is incorporated by reference herein.

### STATEMENT OF GOVERNMENT INTEREST

The U.S. Government may have certain rights in the present invention. This work was partially supported by U.S. Department of Energy contract DE-FC36-04GO14282 and by National Science Foundation IGERT grant number DGE-0221664.

### FIELD OF THE INVENTION

The present invention relates to the field of nanoporous carbon compositions. The present invention also relates to the field of carbon materials chemistry.

### BACKGROUND OF THE INVENTION

Thin film membranes are industrially used in a variety of applications including purification of gases, water, biological fluids, organic and inorganic chemicals. For a variety of reasons, membranes comprised of polymeric resins are widely used in the field.

Polymeric membranes, however, have certain limitations. As an example, as the selectivity of conventional polymer membrane increases, the permeability of the membrane decreases. Robeson, L. M., J. Membr. Sci. 1991, 62, 165. Polymeric materials are also known to have less than optimal stability under intense thermal or chemical conditions. In separation applications, the gases and liquids to be separated can degrade the polymeric membranes or lead to membrane fouling.

As compared to polymeric resins, carbon has a greater thermal stability and chemical stability at elevated temperatures and in harsh environments. The presence of chlorine and extreme pH can also result in deterioration of polymer membranes. Polymeric membranes often have a limited porosity, resulting in high flow resistance and increased energy requirements. Additionally, consistent porosity within polymeric membranes is challenging to achieve.

Polymer nanocomposite membranes incorporating fumed silica, Merkel, T. C.; Freeman, B. D.; Spontak, R. J.; He, Z.; Pinnau, I.; Meakin, P.; Hill, A. J., Science, 2002, 296, 519, or zeolite particles into the polymer matrix are also known and offer improved membrane permeability and separation of large organic molecules over small gases (e.g., CO₂ or H₂), as compared to pure polymer membranes. However, composite membranes are hindered by the difficulties of achieving desirable adhesion between the polymer and particles and also of achieving uniform particle dispersion. In addition, the thermal and chemical stabilities of polymer/ceramic composites are similar to polymer membranes and thus have the same disadvantages.

Crystalline zeolites are another material used for membrane fabrication. However, zeolites can be challenging to process, as they tend to crack, arising from their crystalline nature. Furthermore, it is difficult to form thin zeolitic membranes, typically needed for creating high permeate flux.

Nanoporous carbon membranes have been synthesized by pyrolysis of polymeric precursors, both nongraphitizing natural and synthetic polymers. Due to fragility, they are generally applied on macroporous supports (Strano M. S. and Foley, H. C. AIChE Journal, 2001 47:66-78. Membranes have been fabricated as both planar and tubular forms, with a general thickness of 40-50 micrometers (Rajagopalan, R. and Foley, H. C. Materials Research Society 2003).

Common polymeric precursors for carbon membranes include poly-furfuryl alcohol, polyvinylidene chloride, polyvinylchloride (PVC), polyacrylonitrile (PAN), cellulose, Kapton, phenol formaldehyde, phenolic resin, perfluoroalkoxy (PFA), and polymides (Shiflett, M. B. and Foley, H. C., Journal of Membrane Science, 2000, 179: 275-282; Saufi, S. M. and Ismail, A. F. Carbon 2004 42(2): 241-259). Methods for synthesizing such membranes pose certain challenges, including: limitations of the membrane thickness to greater than about 20 micrometers for the supported membranes, the formation of cracks in the membranes, challenges in the controlling the pore sizes in the resultant membrane; and that the precursors of such membranes are typically limited to organic materials.

Accordingly, there is a demonstrated need in the field for thin, nanoporous membranes that are crack-free while also having tunable pore sizes and high surface areas. There is also a need for methods for synthesizing such compositions and membranes.

### SUMMARY OF THE INVENTION

In meeting the challenges of forming suitable nanoporous compositions, disclosed is a membrane, comprising: a cohesive carbonaceous composition comprising a plurality of nanopores, wherein the plurality of nanopores has an average cross-sectional dimension, as determined by the non-local density functional theory method analysis of nitrogen sorption isotherms, of less than about 7 nm.

Also provided is a method, comprising: treating an inorganic carbon-containing precursor adjacent to a support so as to remove substantially all non-carbon species from the inorganic carbon-containing precursor, wherein the inorganic carbon-containing precursor is situated adjacent to a support, so as to give rise to a supported nanoporous carbonaceous membrane comprising a plurality of nanopores, and wherein the plurality of nanopores comprises an average cross-sectional dimension as determined by the non-local density functional theory method analysis of nitrogen sorption isotherms of less than about 7 nm.

Further provided is a device, comprising: a carbonaceous membrane comprising a plurality of nanopores, wherein the plurality of nanopores comprise a average cross-sectional dimension as determined by the non-local density functional theory method analysis of nitrogen sorption isotherms, of less than about 7 nm, and wherein the carbonaceous membrane is adjacent to a support.

The general description and the following detailed description are exemplary and explanatory only and are not restrictive of the invention, as defined in the appended claims. Other aspects of the present invention will be apparent to those skilled in the art in view of the detailed description of the invention as provided herein.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. In the drawings:

FIG. 1(a) is a schematic of the process flow for carbide-derived carbon membrane formation and FIG. 1(b) depicts optical images of a representative membrane at the corresponding processing stages;

FIG. 2(a) is an SEM micrograph of the matte side of a commercially-available Anodisc™ (Whatman PLC, www.whatman.com) inorganic substrate membrane demonstrating varying porosity, and FIG. 2(b) is an SEM micrograph of the shiny (non-matte) side of an Anodisc™ substrate membrane;

FIG. 3(a) is an SEM micrograph top-view of a representative approximately 500 nm TiC coating on an Anodisc™ substrate before chlorination, FIG. 3(b) is an SEM micrograph cross-section of the Anodisc™ substrate membrane before chlorination, FIG. 3(c) is an SEM micrograph top-view of the TiC coating on the Anodisc™ substrate membrane after chlorination, and FIG. 3(d) is an SEM micrograph cross-section of the TiC coating on the Anodisc™ substrate membrane after chlorination (the morphology and thickness of TiC and carbide-derived carbon (“CDC”) coatings formed on commercially-available Sterlitech™ membranes (Sterlitech, Kent, Wash., www.sterlitech.com) used in other Examples are similar to coatings formed on the Anodisc™ substrates);

FIG. 4 illustrates the pore size distributions of TiC-CDC for a representative sample; relative values of the surface area of the pores have dimensions in the about 0.3 nm to about 7 nm range;

FIG. 5 depicts the flux of nitrogen across a representative porous CDC layer as a function of pressure gradient across the layer;

FIG. 6 depicts Raman spectra (FIG. 6(a)) and TEM micrographs (FIG. 6(b)) of a representative chlorinated TiC film and powder, demonstrating the disordered structure of the carbide-derived carbon membranes;

FIG. 7 depicts filtration of (FIG. 7a) Disperse Orange-11 (molecular formula C₁₅H₁₁NO₂; available from Sigma-Aldrich, www.sigmaaldrich.com) and (FIG. 7b) disperse Blue-14 (C₁₆H₁₄NO₂; Sigma-Aldrich) dye solutions through a representative, comparatively thick CDC membrane;

FIG. 8 depicts the size and geometry of a comparatively thin representative CDC film on bulk carbide;

FIG. 9 illustrates (FIG. 9a) an EDS line scan (average across 6 lines) of ther intensity of potassium and sodium K-lines across the outer ring of a NaCl/KCl droplet dried on the surface of a representative carbon film produced from Ti₃SiC₂ precursor, and (FIG. 9b) an SEM image showing the location of the line scans taken to obtain the averaged data shown in FIG. 9a;

FIG. 10 depicts a fluorescent micrograph of the edge of the dried dye solution droplet on the surface of a representative carbon film produced from a Ti₃SiC₂ precursor (florescent pink and blue dyes were used in the initial mixture)—dye separation is evident in the grey-scale image;

FIG. 11 depicts optical images of the as-received Sterlitech™ ceramic membrane (left section of figure), the Sterlitech™ ceramic membrane covered with TiC (middle section of figure), and the Sterlitech™ ceramic membrane covered with thin layer of CDC obtained by chlorination of the TiC-covered membrane (right section of figure); and

FIG. 12 illustrates permeation of various gases through a representative CDC-coated Sterlitech™ ceramic membrane as a function of pressure difference—variations in the flow rate are visible at higher pressures.

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

Provided are membranes, such membranes including a cohesive carbonaceous composition that include comprising a plurality of nanopores. The plurality of nanopores has an average cross-sectional dimension, as determined by the non-local density functional theory method analysis of nitrogen sorption isotherms, of less than about 7 nm.

The cohesive carbonaceous composition can be characterized as derived from a carbide, a carbonitride, or any combination thereof. In some cases, the cohesive carbonaceous composition can be characterized as having a disordered microstructure.

The plurality of nanopores can be characterized as being substantially slit-shaped. In other embodiments, the plurality of nanopores is characterized as being substantially cylindrical in shape. In some cases, the plurality of nanopores can include both slit-shaped and cylindrical nanopores. Suitable nanopores can be unimodal in pore size distribution.

The plurality of nanopores can have an average cross-sectional dimension, as determined by the non-local density functional theory method analysis of nitrogen sorption isotherms, of less than about 3 nm, or in some embodiments, less than about 1 nm.

Permeability was calculated wherein the permeance, K, was defined as

$$K = \frac{J}{Δ p} ,$$

where Δp—is the pressure gradient across the membrane, J—is the gas flux. The resistance to flow, defined as

$$R = \frac{1}{K} ,$$

across the membrane layer was evaluated as the difference between the gas flow resistance through the chlorinated support (e.g., Sterlitech™) membranes with and without membrane coatings: R_{CDC}=R_{with}−R_{without}. Accordingly, the permeance of the membrane layer was evaluated as:

$${K}_{CDC} = \frac{{K}_{with} \cdot {K}_{without}}{{K}_{without} - {K}_{with}} .$$

The permeability, P, was then termed according to the established convention of P=L·K, where L—is the thickness of the active layer. Under this analysis, the cohesive carbonaceous composition can be characterized as having a permeability in the range of from about 1 Barrer to about 500 Barrers (1 Barrer=7.5005×10⁻¹⁵ m² s⁻¹ kPa⁻¹) or from about 50 Barrers to about 200 Barrers, or from about 100 to about 150 Barrers. The permeability of the composition can vary according to the user's needs.

Also provided are methods, such methods including treating an inorganic carbon-containing precursor adjacent to a support so as to remove substantially all non-carbon species from the inorganic carbon-containing precursor, wherein the inorganic carbon-containing precursor is situated adjacent to a support, so as to give rise to a supported nanoporous carbonaceous membrane comprising a plurality of nanopores, and wherein the plurality of nanopores has an average cross-sectional dimension, as determined by the non-local density functional theory method analysis of nitrogen sorption isotherms, of less than about 7 nm.

The methods of the present invention can also include the step of depositing the inorganic carbon-containing precursor adjacent to the support before treating the inorganic carbon-containing precursor. Such deposition can be suitably accomplished by chemical vapor deposition, by physical vapor deposition, sputtering, magnetron sputtering, or any combination thereof, before treating. These and other suitable deposition techniques are known to those of ordinary skill in the art.

The plurality of nanopores may be characterized as substantially slit-shaped, or as substantially cylindrical in shape, or as any combination thereof. Typically, the plurality of nanopores has an average cross-sectional dimension as determined by the non-local density functional theory method analysis of nitrogen sorption isotherms of less than about 3 nm, or less than about 1 nm.

Suitable inorganic carbon-containing precursors include carbides, carbonitrides, or any combination thereof. Suitable carbides include binary carbides, ternary carbides, or any combination thereof, and are commercially available from, for example, Alfa Aesar, Inc. (www.alfaaesar.com). Inorganic carbon-containing precursors appropriate for use in the present invention may be amorphous, crystalline, nanocrystalline, microcrystalline, crystalline, or any combination thereof.

Suitable inorganic carbon-containing precursors can include at least one metal. Suitable metals include Ti, Zr, Hf, V, Ta, Nb, Mo, W, Fe, Al, Si, B, Ca, Cr, or any combination thereof. Titanium carbide is considered an especially suitable precursor.

The inorganic carbon-containing precursor can, in some configurations, be characterized as a film or layer, suitably having a thickness in the range of from about 5 nm to about 1000 micrometers, or in the range of from about 30 nm to about 500 micrometers, or in the range of from about 300 nm to about 100 micrometers, or even in the range of from about 500 nm to about 1 micrometer. Film thicknesses up to about 1 centimeter are contemplated. The inorganic carbon-containing precursor can be characterized as being a thick film or, in some embodiments, as being in bulk, powder, or particle form.

Suitable supports are porous, but can be nonporous or even a combination of porous and nonporous material. Suitable supports include microfiltration substrates (available from Sterlitech Corporation, Kent, Wash.), and other porous media (e.g., Anodisc™ 25, Whatman International Ltd, Maidstone, England). Supports can be inorganic in composition; one suitable support composition can be aluminum oxide or a derivative thereof, e.g., Anodisc™ 25.

Suitable treating can include halogenating, heating, sintering, or any combination thereof. Chlorine is considered an especially suitable halogen. Such treatments can be conducted at a temperature in the range of from about 10° C. to about 2000° C., or in the range of from about 100° C. to about 1000° C., or in the range of from about 300° C. to about 700° C. Treating can be carried out in a reactor, a furnace, or other suitable vessel. In certain embodiments, excess halogen is collected by bubbling through a liquid gas trap or other system known in the art.

In some embodiments, the disclosed methods can include the step of cooling the supported nanoporous carbonaceous membrane. Cooling suitably includes exposing the supported nanoporous carbonaceous membrane to temperature gradient, to a fluid, to a heat sink, or any combination thereof. The present invention also includes supported nanoporous carbonaceous membranes produced by the disclosed methods.

The present invention also provides devices. Such devices include carbonaceous membranes comprising a plurality of nanopores, wherein the plurality of nanopores comprise a average cross-sectional dimension as determined by the non-local density functional theory method analysis of nitrogen sorption isotherms, of less than about 7 nm, and wherein the carbonaceous membrane is adjacent to a support.

Suitable carbonaceous membranes can be derived from an inorganic carbon-containing precursor. Suitable inorganic carbon-containing precursors are described elsewhere herein, as are the dimensions and characteristics of a suitable plurality of nanopores. The inorganic carbon-containing precursor is suitably deposited adjacent to the support by physical vapor deposition, chemical vapor deposition, sputtering, magnetron sputtering, or any combination thereof. Suitable supports may be porous, nonporous, or any combination thereof.

Suitable devices as provided herein are capable of separating, filtering, purifying, adsorbing, sieving, or any combination thereof, and may be applied to atoms, ions, molecules, proteins, macromolecules, biological molecules, gases, liquids, and the like. Without being bound by any particular theory of operation, it is believed that such devices function by filtering, adsorbing, separating, purifying, sieving, or any combination thereof.

As one non-limiting example, supported nanoporous membranes can be used to separate a mixture of two or more different species. Without being bound to any particular theory of operation, it is envisioned that the inventive devices, in certain configurations, exploit the difference in the sizes of the species to be separated (e.g., molecules, proteins, viruses, bacteria, antibodies, tissues, cells, ions, atoms, etc.) or differences in the diffusivity of the species to be separated through the membrane.

In one non-limiting example, species in the mixture that are relatively small or have a relatively faster diffusion rate may travel through the membrane faster than the other species in the mixture, thus allowing separation on that basis. Suitable membrane supports may be porous or non-porous depending on the needs of a particular application. The inventive devices are useful in purifying devices, wherein, for example, the inventive device can be used to separate impurities (e.g., bacteria) from a water sample so as to render the water safe for human consumption.

In other embodiments, the inventive devices can be used to separate, identify, or purify components in a mixture based on the differential affinities of the components for the porous carbon membranes—effectively a stationary adsorbing medium—through which the mixture components pass. In alternate embodiments, it is envisioned that the porous carbon can be impregnated with gas, a liquid, or other mobile medium in order to effect a separation based on the differential affinities of the mixture components for the gas, liquid, or other mobile medium of the device. It is envisioned that such devices allow for the separation of mixtures that include two or more components of interest. As discussed elsewhere herein, the membrane support can be porous or non-porous, depending on the needs of a particular application. As a non-limiting example, a porous support can be used in filtration applications A non-porous support can be used in electrodes, catalyst supports or other suitable applications.

The inventive devices can, it is envisioned, be used in electrochemical cells or in electrodes—such applications would take advantage of the relatively high surface areas of the membranes of the present invention. The devices can also be used as catalyst supports—it is expected that the high surface areas of the inventive devices would present a large area on which catalyst can reside and react with reacting species introduced to the devices.

The inventive devices are also, in certain configurations, capable of adsorbing water from a fluid wherein—without being bound to any particular theory of operation—the devices are configured such that the water adsorbs to the surfaces of the membrane as the fluid passes along, across, or through the membrane.

At all events, it is envisioned that those having ordinary skill in the art will optimize the pore size and thickness of the inventive membranes to suit individual applications and individual mixtures to be processed or separated.

### EXAMPLES AND ILLUSTRATIVE EMBODIMENTS

The following are non-limiting examples that are representative only and do not necessarily restrict the scope of the present invention.

### Example 1

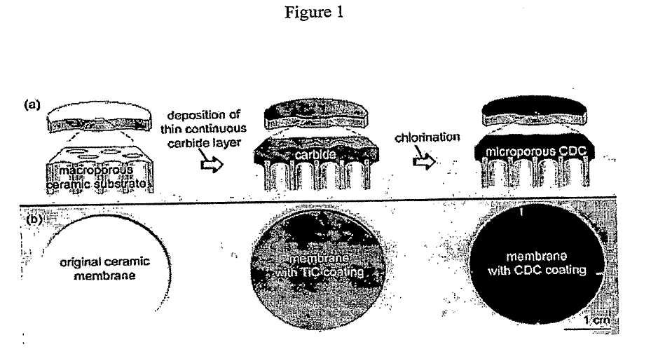

Samples were prepared according to the scheme in FIG. 1. Two porous ceramic substrates were used to support a CDC thin film. The first was a porous microfiltration substrate (Sterlitech Corporation, Kent, Wash.), 47 mm in diameter and 2.5 mm thick. The second, (Anodisc™ 25, Whatman International Ltd, Maidstone, England) had a diameter of 25 mm and 0.08 mm thickness. Prior to sputtering the inorganic carbon-containing precursor, the polypropylene ring around the Anodisc™ 25 substrate was removed by heating of the substrates to 600° C. in air for 5 minutes; the heating rate was 5° C./min.

An approximately 500 nm layer of TiC was deposited on the substrates by magnetron sputtering. Wendler, B.; Danielewski, M.; Przybylski, K.; Rylski, A.; Kaczmarek, L.; Jachowicz, M., Journal of Materials Processing Technology, 2006, 175, 427. During sputtering, the ceramic support membranes were attached to a rotating table using a steel wire. The vacuum chamber was pumped down to a residual pressure of about 10⁻⁶ Torr. The motor drive of the rotary table was then switched on at an angular speed of 0.3 rad/s. Argon was introduced into the vacuum chamber at a flow rate of 0.18 sccm, resulting in an equilibrium pressure of 2×10⁻³ Torr. The magnetron discharge was used with 3.0 kW power for all four magnetrons.

After sputtering began, acetylene was introduced into the chamber until the total pressure began to increase. After 840 seconds, the magnetrons were switched off and the flows of Ar and C₂H₂ were reduced to zero and the vacuum chamber was slowly vented.

For CDC synthesis, the TiC powder (Alfa Aesar, particle size 2 micrometers) or TiC-coated Anodisc™ 25 discs were placed in a horizontal quartz tube furnace one inch in diameter and purged with Ar at a flow rate of 40 sccm at 25° C. for 2 hours, followed by chlorine with a flow rate of 20 sccm at 350° C. for 30 minutes. The larger TiC-coated Sterlitech™ discs were placed in a wider (2.5 inch) horizontal tube furnace and purged with Ar at a flow rate of 40 sccm at 25° C. for 2 hrs. The temperature was then increased to 120° C. for 20 hrs to remove any absorbed oxygen from the system. This was followed by chlorination at a flow rate of 20 sccm at 350° C. for 30 min. A simplified chlorination reaction can be described as (Yushin, G.; Gogotsi, Y.; Nikitin, A., Carbide Derived Carbon, In Nanomaterials Handbook; Gogotsi, Y., Ed.; CRC Press, 2006; p 237; Dash, R. K.; Chmiola, J.; Yushin, G. N.; Gogotsi, Y.; Laudisio, G.; Singer, J.; Fischer, J. E.; Kucheyev, S. Carbon, 2006, 44, 2489):

TiC(s)+2Cl₂(g)=C(s)+TiCl₄(g)

The synthesized thin film CDC membranes were cooled down under the flow of Ar to room temperature and removed for characterization. A comparatively low chlorination temperature was used because of its attractiveness to potential industrial production. In order to better understand the flow through the CDC membrane, a Sterlitech™ support was chlorinated under the same conditions.

Electron microscopy and energy dispersive spectroscopy (EDS) was performed at 20 kV using a FEI (US) XL30 environmental scanning electron microscope (SEM) equipped with EDAX (US) EDS system. Gas sorption analysis was done using Quantachrome (US) Autosorb-1 with argon adsorbate at −195.8° C.

Pore size distribution of the CDC was determined using the non-local density functional theory (NLDFT) method analysis of nitrogen sorption isotherms provided by Quantachrome's data reduction software (version 1.27). Ravikovitch, P. I.; Vishnyakov, A.; Neimark, A. V., Physical Review E, 2001, 6401. Raman analysis was performed using a Renishaw (UK) 1000/2000 micro-spectrometer with an excitation wavelength of 514 nm (Ar ion laser). Transmission electron microscopy (TEM) analysis was performed on a microscope (JEOL 2010F, Japan) equipped with a Gatan GIF imaging filter and operated at an acceleration voltage of 200 kV. The TEM samples were prepared by scratching the CDC coating and the deposition of the flakes on a lacey-carbon coated copper grid (200 mesh).

To confirm gas permeation through the carbon membrane, nitrogen gas was passed through the membrane system, with the nitrogen passing through the carbon layer first, then passing through the macroporous support layer to prevent potential delamination of the CDC. The membrane was attached to a glass fitting connected to gas lines with silicone adhesive. The entire assembly was submerged in a water bath under atmospheric pressure to monitor for leaks. Nitrogen was also passed through a chlorinated Sterlitech™ membrane that did not have a CDC layer so as to determine the permeation rate of the Sterlitech™ membrane support treated at identical conditions.

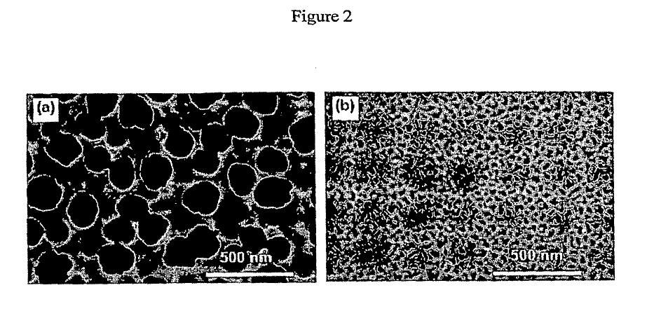

Plane view and cross-sectional SEM analysis was performed on the membranes during each stage of the process. Both the as-received Sterlitech™ and Anodisc™ 25 substrates were asymmetric in that the pore size was different on either surface of the discs. The cylindrical pores of the Anodisc™ 25 increased in diameter from about 50 nm on one side of the sample to about 200 nm on the other side (FIG. 2). Voids between sintered ceramic particles constituted the pores of the Sterlitech™ membrane (not shown). Their shape was irregular and the pore size distribution was broad and difficult to estimate using SEM. The average pores appeared to be about 150 nm on the smoother side used for further TiC deposition and about 500 nm on the opposite side.

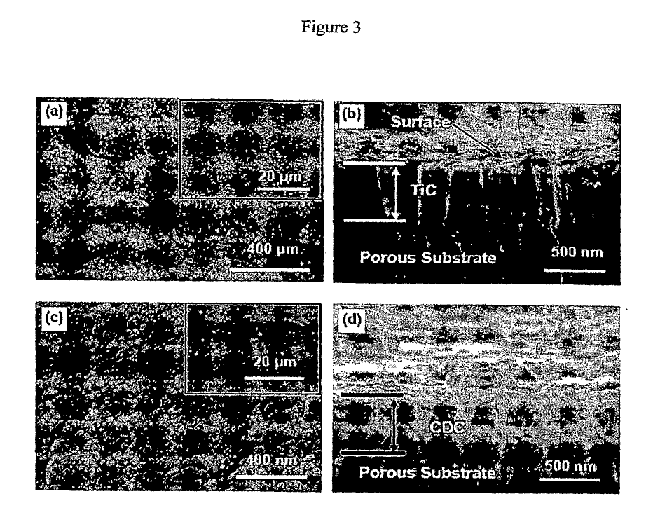

The sputtered TiC thin film (FIGS. 3a, 3b) formed a continuous layer over both porous discs (only the Anodisc™ 25 samples are shown) with occasional formation of tiny TiC spheres on the surface (inset, FIG. 3a). The thickness of the TiC layer was 0.5 micrometers as determined by SEM (FIG. 3b). EDS of the CDC indicated that less than about 1% Ti remained in the films. SEM images of the TiC-CDC surface (FIG. 3c) and fractured cross-section (FIG. 3d) showed films that were crack-free and void of delamination. The thickness of the coating did not change during chlorination (FIGS. 3b, 3d), confirming the conservation of carbide shape during the CDC formation.

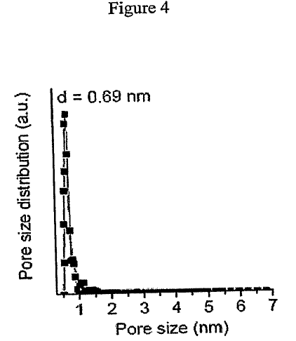

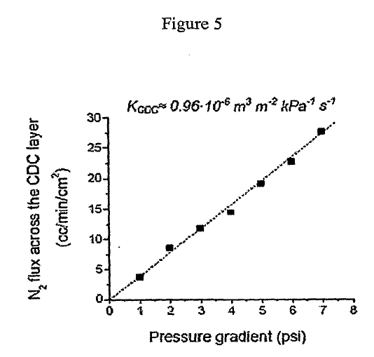

In addition, a narrow pore size distribution was observed, with an average pore size of about 7 nm See FIG. 4. Although TiC-coated ceramic membranes were not permeable to nitrogen, CDC-coated membranes permitted substantial throughput of nitrogen. See FIG. 5.

### Example 2

For the synthesis of nanoporous membranes, a uniform crack-free thin film of titanium carbide was applied onto a porous alumina disc, Anodisc™ 25 (Whatman International Ltd, Maidstone, England) using a magnetron sputtering technique. The film thickness was about 0.5 microns as determined by scanning electron microscope, see FIG. 3b.

The coated disc was loaded into the hot zone of a horizontal quartz tube furnace. The quartz tube inner diameter dimension was 25 mm. The tube was Ar purged for 30 minutes at approximately 60 sccm before heating at a rate of approximately 30° C./minute up to the desired temperature. Once the temperature reached 400° C. and stabilized, the Ar flow was stopped and a 3-hour chlorination began in Cl₂ flowing at a rate of 20 sccm. Evolved metal chlorides were trapped in a water-cooled condenser at the outlet of the heating zone. After the completion of the chlorination process, the samples were cooled under a flow of Ar to remove residual metal chlorides from the pores, and were removed for further analyses. To avoid a back-stream of air, the exhaust tube was connected to a bubbler filled with sulfuric acid.

Energy dispersive spectroscopy (EDS) confirmed the complete removal of titanium after chlorination; see Table A.

TABLE A
Elemental Composition at Synthesis Stages (Atomic %)

| Element | Anodisc ™ | TiC | TiC-CDC |
|---|---|---|---|
| C | 4 | 50 | 40 |
| Al | 33 | 26 | 29* |
| O | 60 | 12 | 28* |
| Ti | 0 | 12 | <1 |
| Cl | 0 | 0 | 2 |
| P | 2 | 1 | 1* |

Table A: Energy dispersive spectroscopy results of elemental composition of three major synthesis stages of the carbon thin film. Based on results, the titanium was essentially removed from the thin film. Results were obtained using 25 kV accelerating voltage and are rounded to the nearest atomic percent.
A *marker means the observed signal was from the Anodisc ™ support membrane.

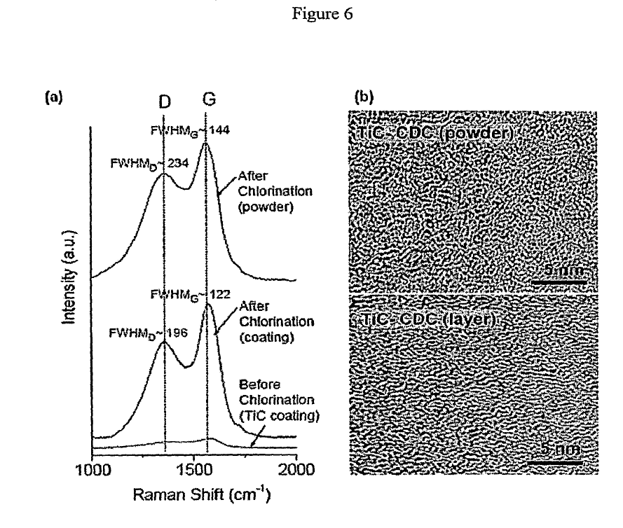

Further confirmation of carbide conversion to carbon was found using Raman micro spectroscopy. See FIG. 6a. Raman micro spectroscopy was employed using a 50× objective and a 514 nm Argon ion laser to measure the D- and G-band peaks, generally associated with the presence of carbon. TEM inspection of the CDC layer revealed a disordered microstructure. FIG. 6b.

### Example 3

Nanoporous carbon membrane was prepared by chlorinating sintered 3 mm thick Ti₃SiC₂ ceramics at 1000° C. The coated disc was loaded into the hot zone of a horizontal quartz tube furnace. The quartz tube inner diameter dimension was 22 mm. The tube was Ar purged for 30 minutes at about 60 sccm before heating at a rate of approximately 30° C./min up to 1000° C. Once the temperature reached 1000° C. and stabilized, the Ar flow was stopped and a 4-hour chlorination began in Cl₂ flowing at a rate of 20 sccm. Evolved metal chlorides were trapped in a water-cooled condenser at the outlet of the heating zone. After the completion of the chlorination process, the samples were cooled under a flow of Ar to remove residual metal chlorides from the pores, and removed for further analyses. In order to avoid a back-stream of air, the exhaust tube was connected to a bubbler filled with sulfuric acid.

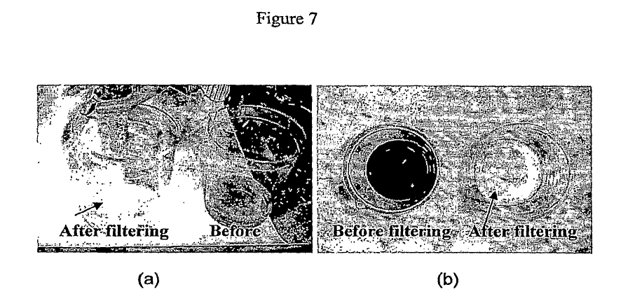

Filtration experiments were performed on the produced hydrophilic self-supported membranes. A CDC membrane (having approximately 1 cm² open area) was glued between two open ended plastic tubes. The top portion of the tube was filled with a dye solution and pressurized to 1.5 bar. Two dyes with molecular weights of 266 and 235 were chosen. Both dyes were successfully filtered (and the solution was successfully purified). A flow rate of approximately 40 1·m⁻²·h⁻¹ was recorded. As seen in FIG. 7, filtration of Orange-11 dye (formula: C₁₅H₁₁NO₂) (FIG. 7a), and Blue-14 due (formula: C₁₆H₁₄NO₂) (FIG. 7b) by the synthesized membrane was efficient.

### Example 4

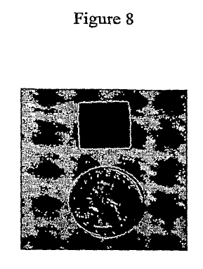

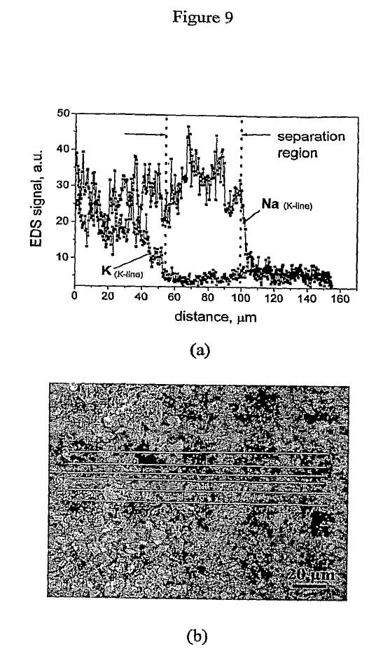

A bulk piece of sintered Ti₃SiC₂, 15×15×3 mm was chlorinated for 5 minutes under a chlorine gas flow rate of 20 sccm to produce a thin coating of CDC on bulk carbide (FIG. 8). A 3.0 M aqueous solution of NaCl and KCl were combined to form a mixture (an aqueous solution of both NaCl and KCl). Using a pipette, a single drop of the NaCl/KCl mixture was placed onto the center of the CDC film and allowed to dry naturally. Once dry, the sample was observed in the FEI XL-30 field emission SEM equipped with EDS detector. EDS was performed at 20 kV with a spot size of 3. The EDS analysis revealed a space separation of sodium and potassium elements in the outer ring of the dried droplet (FIG. 9). The sodium chloride diffused further than the potassium chloride from the initial location of the droplet (FIGS. 9a, 9b).

### Example 5

The sample described in Example 4 was also used in this experiment. A droplet of an aqueous mixture containing two fluorescent dyes encapsulated by polystyrene was dropped onto the CDC surface and allowed to dry naturally. The two polystyrene-encapsulated dyes were a blue fluorescing dye encapsulated by polystyrene to form spheres of 0.90 micrometers; and a pink fluorescing dye, encapsulated by polystyrene to form spheres of 0.33 micrometers. Both fluorescing aqueous particle solutions containing 1% solids were products of Bangs Laboratory, Fishers, Ind.

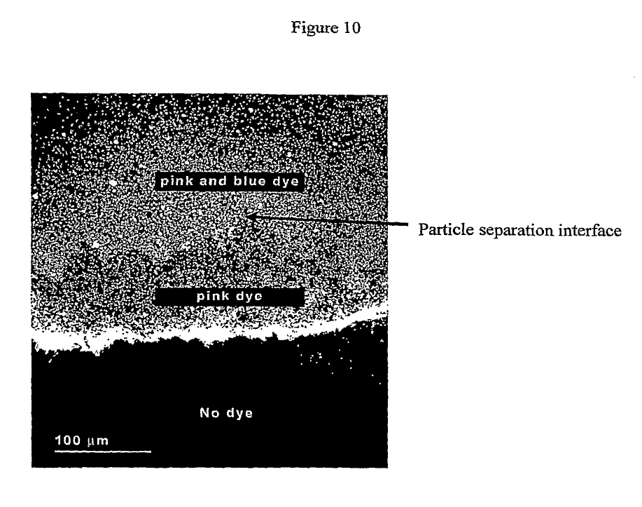

After the droplet completely dried, it was viewed using a UV filtered optical microscope (Zeiss, Thornwood, N.Y.). Using a 20× objective, particle separation was viewed along the outer edge of the dried droplet. (FIG. 10). The smaller particles, bearing pink dye, diffused further along the CDC thin film than did the larger particles, which bore blue dye.

### Example 6

For the synthesis of NPC membranes, a procedure similar to that of Example 1 was employed, using 47M014 porous substrates obtained from Sterlitech Corporation, 47 mm in diameter and 2.5 mm thick. To accommodate these substrates, the size of the quartz tube was increased to approximately 70 mm in inner diameter and the Ar purging time was increased to approximately 6 hours at approximately 60 sccm before 3 hours of chlorination at approximately 400° C.; the Cl₂ was flowed at a rate of approximately 30 sccm. After the completion of the chlorination process, the samples were cooled under a flow of Ar to remove residual metal chlorides from the pores, and removed for further analyses.

In order to identify variations in the permeation of gases through the CDC membrane, argon, helium, nitrogen, and methane were individually passed through the membrane system with the gases passing through the carbon layer first, and exhausting at the macroporous support layer. A pressure gauge was connected at the inlet, along with electronic flowmeters at both the inlet and outlet of the membrane. The membrane was attached to a glass fitting connected to gas lines with silicone adhesive. The entire membrane, silicone, glass assembly was submerged in a water bath to monitor for leaks. Gases were also passed through as-received and the chlorinated Sterlitech™ membrane without a deposited carbon layer to determine the permeation rate of the Sterlitech™ membrane support. A noticeable difference in gas permeation was observed between a Sterlitech™ membrane as-received, and a Sterlitech™ membrane chlorinated for 3 hours at 400° C. with no carbide or carbon coating.

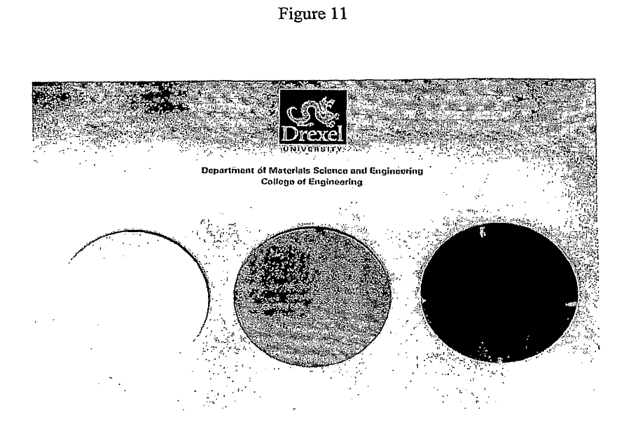

After chlorinating the carbide-coated discs, the carbide coating had transformed to carbon, evidenced by a visible change in coating color. (FIG. 11). Energy dispersive spectroscopy was used to determine if sample was completely chlorinated. Less than 5% of Ti was found in the sample, and, without being bound to any mode of operation, it was assumed that the layer was fully transformed to carbon.

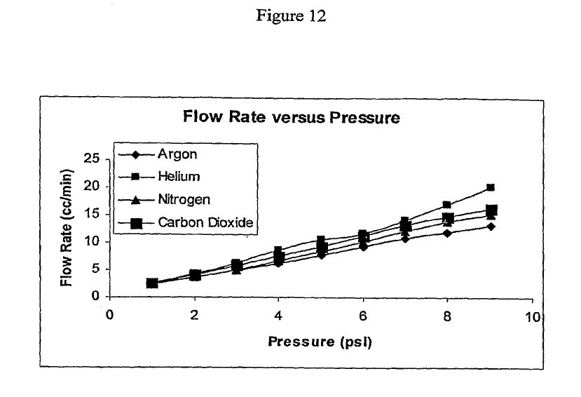

FIG. 12 illustrates the flowrate of various gases at the inlet of a representative CDC membrane plotted against the pressure difference across the membrane. In this particular example, greater variations in the flow rate were observed at higher pressures. As the chlorinated Sterlitech™ ceramic demonstrates smaller resistance to flow (data not shown), the CDC layer was responsible for the observed variations in the gas flow kinetics.

What is claimed:

1. A membrane, comprising:
a cohesive carbonaceous composition comprising a plurality of nanopores, wherein the plurality of nanopores is characterized as having an average cross-sectional dimension, as determined by the non-local density functional theory method analysis of nitrogen sorption isotherms, of less than about 7 nm.

2. The membrane of claim 1, wherein the cohesive carbonaceous composition is derived from a carbide, a carbonitride, or any combination thereof.

3. The membrane of claim 1, wherein the plurality of nanopores is characterized as being substantially slit-shaped.

4. The membrane of claim 1, wherein the plurality of nanopores is characterized as being substantially cylindrical in shape.

5. The membrane of claim 1, wherein the plurality of nanopores has an average cross-sectional dimension, as determined by the non-local density functional theory method analysis of nitrogen sorption isotherms, of less than about 3 nm.

6. The membrane of claim 1, wherein the plurality of nanopores has an average cross-sectional dimension, as determined by the non-local density functional theory method analysis of nitrogen sorption isotherms, of less than about 1 nm.

7. The membrane of claim 1, wherein the plurality of nanopores are characterized as having a unimodal pore size distribution.

8. The membrane of claim 1, wherein the cohesive carbonaceous composition is characterized as having a disordered microstructure.

9. The membrane of claim 1, wherein the cohesive carbonaceous composition is characterized as having a permeability in the range of from about 1 Barrer to about 500 Barrers.

10. The membrane of claim 1, wherein the cohesive carbonaceous composition is characterized as having a permeability in the range of from about 50 Barrers to about 200 Barrers.

11. The membrane of claim 1, wherein the cohesive carbonaceous composition is characterized as having a permeability in the range of from about 100 Barrers to about 150 Barrers.

12. A method, comprising:
treating an inorganic carbon-containing precursor adjacent to a support so as to remove substantially all non-carbon species from the inorganic carbon-containing precursor,
wherein the inorganic carbon-containing precursor is situated adjacent to a support, so as to give rise to a supported nanoporous carbonaceous membrane comprising a plurality of nanopores, and
wherein the plurality of nanopores is characterized as having an average cross-sectional dimension as determined by the non-local density functional theory method analysis of nitrogen sorption isotherms of less than about 7 nm.

13. The method of claim 12, further comprising the step of depositing the inorganic carbon-containing precursor adjacent to the support by chemical vapor deposition, physical vapor deposition, sputtering, magnetron sputtering, or any combination thereof, before treating the inorganic carbon-containing precursor.

14. The method of claim 12, wherein the plurality of nanopores is characterized as substantially slit-shaped.

15. The method of claim 12, wherein the plurality of nanopores is characterized as substantially cylindrical in shape.

16. The method of claim 12, wherein the plurality of nanopores is characterized as having an average cross-sectional dimension as determined by the non-local density functional theory method analysis of nitrogen sorption isotherms of less than about 3 nm.

17. The method of claim 12, wherein the plurality of nanopores is characterized as having an average cross-sectional dimension as determined by the non-local density functional theory method analysis of nitrogen sorption isotherms of less than about 1 nm.

18. The method of claim 12, wherein the inorganic carbon-containing precursor comprises a carbide, a carbonitride, or any combination thereof.

19. The method of claim 18, wherein the carbide comprises a binary carbide, a ternary carbide, or any combination thereof.

20. The method of claim 12, wherein the inorganic carbon-containing precursor is characterized as amorphous, crystalline, nanocrystalline, microcrystalline, crystalline, or any combination thereof.

21. The method of claim 12, wherein the inorganic carbon-containing precursor comprises at least one metal.

22. The method of claim 21, wherein the metal comprises Ti, Zr, Hf, V, Ta, Nb, Mo, W, Fe, Al, Si, B, Ca, Cr, or any combination thereof.

23. The method of claim 12, wherein the inorganic carbon-containing precursor is characterized as having a thickness in the range of from about 5 nm to about 1000 micrometers.

24. The method of claim 12, wherein the inorganic carbon-containing precursor is characterized as having a thickness in the range of from about 30 nm to about 500 micrometers.

25. The method of claim 12, wherein the inorganic carbon-containing precursor is characterized as having a thickness in the range of from about 300 nm to about 100 micrometers.

26. The method of claim 12, wherein the inorganic carbon-containing precursor is characterized as having a thickness in the range of from about 500 nm to about 1 micrometer.

27. The method of claim 12, wherein the inorganic carbon-containing precursor is characterized as being in a powder form, as being in a bulk form, as being in particle form, or any combination thereof.

28. The method of claim 12, wherein the support is porous.

29. The method of claim 12, wherein the support is nonporous.

30. The method of claim 12, wherein the support comprises an inorganic composition.

31. The method of claim 30, wherein the inorganic composition comprises aluminum oxide.

32. The method of claim 12, wherein treating the inorganic carbon-containing precursor comprises halogenating, heating, sintering, or any combination thereof.

33. The method of claim 32, wherein the inorganic carbon-containing precursor is treated at a temperature in the range of from about 10° C. to about 2000° C.

34. The method of claim 32, wherein the inorganic carbon-containing precursor is treated at a temperature in the range of from about 100° C. to about 1000° C.

35. The method of claim 32, wherein the inorganic carbon-containing precursor is treated at a temperature in the range of from about 300° C. to about 700° C.

36. The method of claim 12, further comprising the step of cooling the supported nanoporous carbonaceous membrane.

37. The method of claim 36, wherein the cooling comprises exposing the supported nanoporous carbonaceous membrane to a temperature gradient, to a fluid, to a heat sink, or any combination thereof.

38. A supported nanoporous carbonaceous membrane produced by the method of claim 12.

39. A device, comprising:
a carbonaceous membrane comprising a plurality of nanopores,
wherein the plurality of nanopores is characterized as having an average cross-sectional dimension as determined by the non-local density functional theory method analysis of nitrogen sorption isotherms, of less than about 7 nm, and
wherein the carbonaceous membrane is directly adjacent to a support.

40. The device of claim 39, wherein the carbonaceous membrane is derived from an inorganic carbon-containing precursor.

41. The device of claim 40, wherein the inorganic carbon-containing precursor is deposited directly adjacent to the support by physical vapor deposition, chemical vapor deposition, sputtering, magnetron sputtering, or any combination thereof.

42. The device of claim 39, wherein the support is porous, nonporous, or any combination thereof.

43. The device of claim 39, wherein the plurality of nanopores is characterized as having an average cross-sectional dimension, as determined by the non-local density functional theory method analysis of nitrogen sorption isotherms, of less than about 3 nm.

44. The device of claim 39, wherein the plurality of nanopores is characterized as having an average cross-sectional dimension, as determined by the non-local density functional theory method analysis of nitrogen sorption isotherms, of less than about 1 nm.

45. The device of claim 39, wherein the plurality of nanopores is characterized as having a unimodal pore size distribution.

46. The device of claim 39, wherein the composition is characterized as having a disordered microstructure.

47. The device of claim 39, wherein the plurality of nanopores is characterized as being substantially slit-shaped.

48. The device of claim 39, wherein the plurality of nanopores is characterized as being substantially cylindrical in shape.

49. The device of claim 39, wherein the carbonaceous membrane is characterized as having a permeability to nitrogen gas in the range of from about 1 Barrers to about 500 Barrers.

50. The device of claim 39, wherein the carbonaceous membrane is characterized as having a permeability to nitrogen gas in the range of from about 20 Barrers to about 200 Barrers.

51. The device of claim 39, wherein the carbonaceous membrane is characterized as having a permeability to nitrogen gas in the range of from about 50 Barrers to about 100 Barrers.

52. The device of claim 39, wherein the device is capable of separating at least one species, filtering at least one species, purifying at least one species, adsorbing at least one species, sieving at least one species, or any combination thereof.

53. The device of claim 52, wherein a species comprises an atom, a molecule, an ion, a protein, a biological market, a macromolecule, or any combination thereof.

54. The device of claim 39, wherein the device is used in filtering, adsorbing, separating, purifying, sieving, or any combination thereof.
